(19) United States
(12) Patent Application Publication
(10) Pub. No.: US 2026/0311784 A1
(43) Pub. Date: Oct. 8, 2026

(54) 1.5T OTP Memory And Method For Preparing Same

(71) Applicant: Shanghai Huali Integrated Circuit Corporation, Shanghai (CN)

(72) Inventors: Yafeng QIAN, Shanghai (CN); Duo SHAN, Shanghai (CN)

(73) Assignee: Shanghai Huali Integrated Circuit Corporation, Shanghai (CN)

(21) Appl. No.: 19/194,044

(22) Filed: Apr. 30, 2025

(30) Foreign Application Priority Data
Apr. 7, 2025 (CN) 2025104294731

(51) Int. Cl. G11C 17/16; G11C 17/18; H10B 20/25

(52) U.S. Cl. CPC G11C 17/16; G11C 17/18; H10B 20/25

(57) ABSTRACT

A 1.5T OTP memory and a method for preparing the same are provided; a program gate can be fabricated to an STI structure by only changing the morphology of a gate structure mask from a standard process mask without additional process steps, and both sides of each single program gate can be programmable separately, so as to achieve a higher density of 1.5T programming, and to increase the integration degree of the OTP memory, thereby realizing miniaturized high-density integration; in addition, anti-fuse structures of the OTP memory utilize electric fields between active areas and respective sides of the program gate, thereby improving the programming efficiency and stability; further, the anti-fuse function can be concentrated around the active area divots, making breakdown regions of the anti-fuses more convergent and controllable.

### CROSS REFERENCE TO RELATED APPLICATION

The present application claims the benefit of priority to Chinese Patent Application No. 202510429473.1, entitled “1.5T OTP MEMORY AND METHOD FOR PREPARING SAME”, filed with CNIPA on Apr. 7, 2025, the disclosure of which is incorporated herein by reference in its entirety for all purposes.

### FIELD OF THE INVENTION

The present disclosure relates to the field of semiconductor manufacturing technology, in particular it relates to a 1.5T OTP memory and a method for preparing the same.

### BACKGROUND OF THE INVENTION

One-Time Programmable (OTP) memory is a type of Non-Volatile Memory (NVM), commonly used for encryption keys, code storage, and parameter calibration. Conventional OTP memories utilize an anti-fuse architecture. An anti-fuse consists of two conductors separated by a dielectric layer. In its unprogrammed state, the dielectric layer acts as an insulator. During programming, a high voltage is applied between the conductors to rupture the dielectric layer, forming a conductive path.

FIG. 1 is a schematic cross-sectional view of a 2T OTP (2 transistor OTP) memory; and FIG. 2 is a schematic top view of a 2×2T OTP memory array, with the dashed box circling one memory unit. The 2T OTP memory includes a semiconductor substrate 110, a select gate 210, a program gate 220 (each gate having a dielectric layer 215), and an active area 310, wherein the program gate 220 constitutes an anti-fuse that can be programmed only once, thus restricting the development of miniaturization and high-density integration of the OTP memory.

Therefore, it is necessary to provide a 1.5T OTP memory and a method for preparing the same.

### SUMMARY OF THE INVENTION

The present disclosure provides a 1.5T OTP memory and a method for preparing the same, to address the difficulty in realizing miniaturization and high-density integration of OTP memory.

The 1.5T OTP memory includes:
a semiconductor substrate, including an STI (shallow trench isolation) structure; and
gate structures, wherein the gate structures are disposed over a semiconductor substrate, and include select gates and a program gate, wherein the program gate is disposed above the STI structure, and edges of the program gate are connected to active areas corresponding to the select gates through active area divots, or STI divots.

Optionally, a perpendicular projection of the program gate overlaps with that of the active areas on the substrate.

Optionally, the perpendicular projection of the program gate does not overlap with that of the active areas on the substrate.

Optionally, a length of each of the active area divots or STI divots is less than 200 nm.

Optionally, an axis of symmetry of the program gate along a perpendicular-to-substrate direction coincides with the axis of symmetry of the STI structure, and the select gates are symmetrically distributed with respect to the axis of symmetry of the program gate.

Optionally, multiple adjacent program gates are connected to form at least one program gate line, multiple adjacent select gates are connected to form at least two word lines, and drain regions corresponding to multiple select gates are connected to form at least one bit line.

The method for fabricating a 1.5T OTP memory includes:
providing a semiconductor substrate;
forming an STI structure in the semiconductor substrate; and
forming gate structures over the semiconductor substrate, wherein the gate structures include select gates and a program gate, wherein the program gate is disposed above the STI structure, and edges of the program gate are connected to active areas corresponding to the select gates through active area divots, or STI divots.

Optionally, the program gate is formed by patterning, and the edges of the program gate overlap with the active areas; or the edges of the program gate are away from the active areas.

Optionally, each of the gate structures includes a gate dielectric layer, which includes a silicon oxide layer, a silicon nitride layer, or a hafnium oxide layer.

Optionally, each of the gate structures includes a gate dielectric layer, which is formed by thermal oxidation.

In the current disclosed 1.5T OTP memory and method for preparing the same, a program gate can be transferred into an STI structure by only changing the morphology of a gate structure patterning mask without additional process steps, and both sides of each single program gate can be programed separately, to achieve a higher density of 1.5T programming, so as to increase the integration degree of the OTP memory, thereby realizing miniaturized high-density integration; in addition, anti-fuse structures of the OTP memory utilize electric fields between active areas and respective sides of the program gate, improving the programming efficiency and stability; further, the anti-fuses can be concentrated around the divots, making breakdown regions of the anti-fuses more convergent and controllable.

### BRIEF DESCRIPTION OF DRAWINGS

FIG. 1 is a schematic cross-sectional view of a 2T OTP memory.

FIG. 2 is a schematic top view of a 2×2T OTP memory array.

FIG. 3 is a flowchart illustrating a method for preparing a 1.5T OTP memory according to embodiments of the present disclosure.

FIG. 4 is a schematic cross-sectional view of a 1.5T OTP memory according to embodiments of the present disclosure.

FIG. 5 is an enlarged partial view of Region A in FIG. 4.

FIG. 6 is an enlarged partial view of a 1.5T OTP memory with a spaced region according to embodiments of the present disclosure.

FIG. 7 is a top view of a 1.5T OTP memory according to embodiments of the present disclosure.

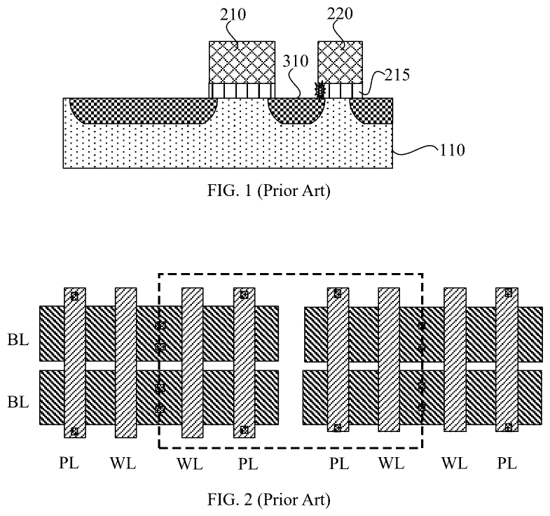

### Reference Numerals

110, 100 Semiconductor Substrate
210, 201 Select Gate
220, 202 Program Gate
215, 205 Gate Dielectric Layer
310, 300 Active Area
400 STI Structure

### DETAILED DESCRIPTION

The embodiments of the present disclosure will be described below. Those skilled can easily understand advantages and effects of the present disclosure according to contents disclosed by the specification. The present disclosure can also be implemented or applied through other different exemplary embodiments. Various modifications or changes can also be made to all details in the specification based on different points of view and applications without departing from the spirit of the present disclosure.

When describing the embodiments of the present disclosure, for better explanation, cross-sectional structural diagrams may be partially enlarged without following the general scale. Moreover, the diagrams are only examples and should not limit the scope of the present disclosure. In addition, the actual production should include the length, width and depth of the three-dimensional space dimensions.

For the convenience of description, spatial relation terms such as “below”, “under”, “beneath”, “on”, “above”, “up”, etc. may be used herein to describe the relationships between an element or feature and other elements or features. It is to be understood that the spatial relationship terms herein are intended to encompass orientations of the device in use or operation that are different from those depicted in the accompanying drawings. The embodiments may include instances where the first and second features are formed in direct contact, as well as instances where additional features are formed between the first and second features, such that the first and second features may not be in direct contact. Furthermore, when a layer is referred to as being “between” two layers, it may be the only layer between the two layers, or there may be one or more intervening layers present.

It should be noted that the drawings provided in this disclosure only illustrate the basic concept of the present disclosure in a schematic way, so the drawings only show the components closely related to the present disclosure. The drawings are not necessarily drawn according to the number, shape and size of the components in actual implementation; during the actual implementation, the type, quantity and proportion of each component can be changed as needed, and the components' layout may also be more complicated.

Referring to FIG. 4, the present disclosure provides a 1.5T OTP memory, including:
a semiconductor substrate 100, including an STI structure 400;
gate structures, wherein gate structures are disposed over the semiconductor substrate 100, and include select gates 201 and a program gate 202, wherein the program gate 202 is disposed above the STI structure 400, and the edges of the program gate 202 are connected to active areas 300 which is also connected to the select gates 201 through active area divots or STI divots.

The semiconductor substrate 100 includes a plurality of active areas 300 (AA), at least two of which are separated by the STI structure 400; the semiconductor substrate 100 may be a silicon substrate or other suitable substrate, such as an N-type doped silicon substrate or a P-type doped silicon substrate. N-type doped or P-type doped well regions may also be selectively formed within the semiconductor substrate 100.

In the following description, the semiconductor substrate 100 is a P-type doped silicon substrate, and N-channel transistors are formed on its surface, for illustrative purposes. It is understood that the semiconductor substrate 100 may also be a N-type doped silicon substrate, and P-channel transistors are formed on its surface,

Each of the gate structures includes a gate dielectric layer 205 and a gate conductive layer disposed on the gate dielectric layer; the gate dielectric layer 205 may include, for example, a silicon oxide layer, a silicon nitride layer, or a hafnium oxide layer; the gate conductive layer may include, for example, a polycrystalline silicon gate conductive layer or a metal gate conductive layer; specific structures, materials, and preparation methods of the gate structures may be adjusted as needed.

With respect to the gate structures, refer to FIGS. 4 and 5, wherein FIG. 5 is the partially enlarged view of Region A in FIG. 4. As an example, the gate structures include select gates 201 and a program gate 202 disposed above the STI structure 400, and edges of the program gate 202 are connected through the ΔX regions to the active areas 300 which are linked to the select gates 201 on each side in FIG. 5; the ΔX regions are where or close to where AA divots are.

An AA divot may be a defect present in the preparation of gate structures; as an example, an AA divot is present where a gate structure, an active area, and an STI structure meet; as shown in FIGS. 4-5, the ΔX regions are where the active areas 300 and the program gate 202 are connected (or more specifically, their perpendicular projections onto the substrate overlap within the ΔX regions), wherein gate dielectric layers formed in the ΔX regions are thinner than the dielectric regions outside the ΔX regions, so that anti-fuse structures of the OTP memory can utilize electric fields between the active areas 300 and respective sides of the program gate 202 in the ΔX regions, improving the programming efficiency and stability; further, the anti-fuse functions can be concentrated around the ΔX regions (AA divots), making breakdown area of the anti-fuses more convergent and controllable.

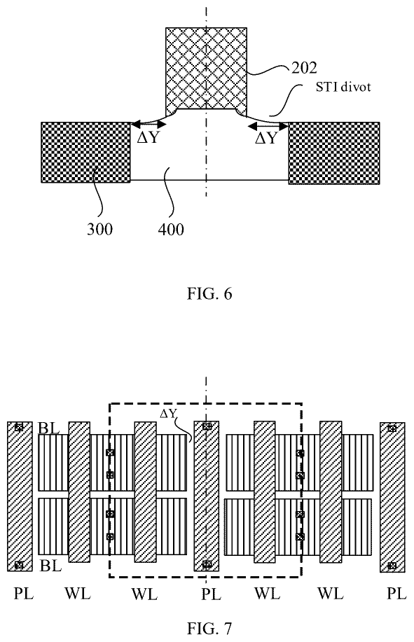

In another embodiment, referring to FIG. 6, perpendicular projections of the program gate 202 and the active areas 300 onto the substrate may also be spaced apart, and the resulting ΔY regions are shown in FIG. 6, through which the anti-fuse structures of the OTP memory can also utilize electric fields between the active areas 300 and respective sides of the program gate 202, improving the programming efficiency and stability. The ΔY regions are where or close to where STI divots are. Further, the anti-fuses can be concentrated around the ΔY regions, making breakdown regions of the anti-fuses more convergent and controllable. The above-mentioned divots may be naturally occurring defects or obtained by damaging the corresponding material layer (i.e., the gate dielectric layer or STI).

Further, the lateral length (width) of each ΔX region or ΔY region (that is, the value of ΔX or ΔY), as in FIGS. 5 and 6, is less than 200 nm, such as 0 nm, 50 nm, 100 nm, 150 nm, 200 nm, and so on. ΔX is the lateral length of the overlapping portion between the program gate 202 and a respective active area 300. ΔY is the lateral distance between the program gate 202 and a respective active area 300.

The specific structure, material, and preparation method of the STI structure 400 may vary depending on application; for example, the STI structure 400 can be filled with silicon oxide. As an example, the program gate 202 is disposed to the STI structure 400 so that each side of the program gate 202 can be separately operated for programing, thereby realizing the programming of a 1.5T OTP memory; that is, functionally speaking, for each programming unit, one select gate 201 and a half program gate 202 are used. Additionally, the program gate 202 disposed above the STI structure 400, increasing the integration degree of the OTP memory, and realizing miniaturized high-density integration.

Further, as an example, as shown in FIGS. 4 to 6, an axis of symmetry of the program gate 202 along a vertical direction coincides with that of the STI structure 400, and the select gates 201 are symmetrically distributed with respect to the axis of symmetry of the program gate 202, making both sides of each single program gate programmable separately, which can further minimize the device, thereby achieving a higher-density 1.5T programmable and miniaturized high-density integration of OTP memory.

FIG. 7 is a top view of the 1.5T OTP memory where the program gate is spaced away from the active areas. As an example, the 1.5T OTP memory includes: a plurality of program gates 202 connected to form at least one program gate line (PL), a plurality of first select gates 201 connected to form at least two word lines (WL) located next to each side of one program gate line (PL), and a plurality of second select gates 201, whose drain regions are connected to form at least one bit line (BL).

As an example, a programming unit includes: the program gate line located above the STI structure 400; the two word lines that are adjacent to the program gate line and symmetrically arranged at each side with respect to the program gate line; and the portions of the bit lines. Such arrangement enables independent programming from both sides of each single program gate.

In another embodiment, the 1.5T OTP memory may also be asymmetrically structured as desired; for example, the structures of FIG. 5 and FIG. 6 may be combined with the program gate overlapping the active region at one side, and spaced away or not overlapping with the active region at another side.

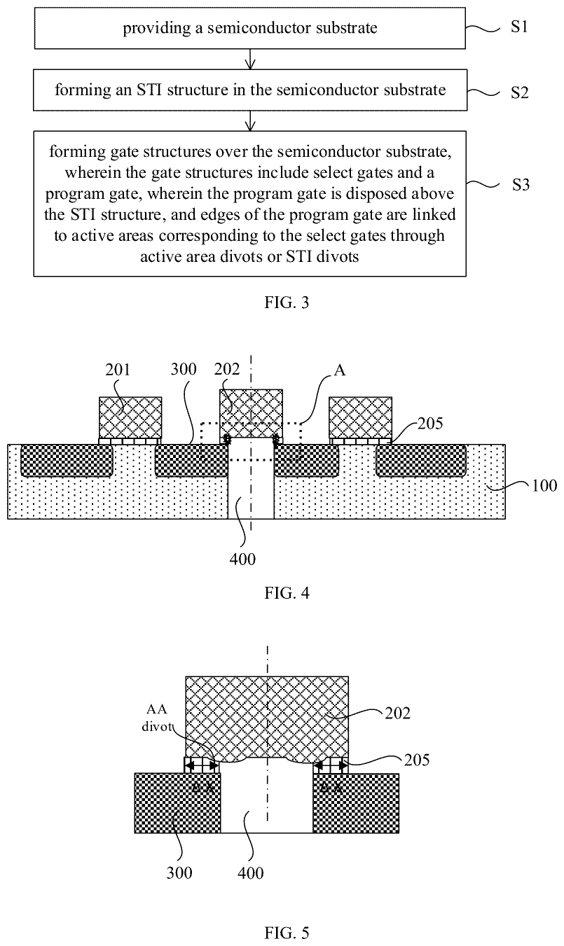

Referring to FIGS. 3 to 7, the present disclosure also provides a method for preparing a 1.5T OTP memory, wherein the 1.5T OTP memory described above may be prepared by said method or other suitable methods.

As an example, the 1.5T OTP memory is prepared by the processes described below; the specific structure, material, and beneficial effects, etc., of the 1.5T OTP memory are detailed in the above device embodiments of the 1.5T OTP memory

As an example, the method for preparing the 1.5T OTP memory includes S1-S3:
S1: providing a semiconductor substrate 100;
S2: forming an STI structure 400 in the semiconductor substrate 100;
S3: forming gate structures over the semiconductor substrate 100, wherein the gate structures include select gates 201 and a program gate 202, wherein the program gate 202 is disposed above the STI structure 400, and edges of the program gate 202 are connected to active areas 300 linking to the select gates 201 through active area divots.

Herein, the program gate 202 can be fabricated at the location of the STI structure 400 by only changing the morphology of a gate structure mask used for a standard 2T OTP without additional process steps, and both sides of each single program gate 202 are programmable separately, so as to achieve a higher density of 1.5T programming, and to increase the integration degree of the OTP memory, thereby realizing miniaturized high-density integration;
in addition, anti-fuse structures of the OTP memory utilize electric fields between active areas 300 and respective sides of the program gate 202, improving the programming efficiency and stability; further, the anti-fuses can be concentrated around the AA divots, making breakdown regions of the anti-fuses more convergent and controllable.

As an example, the program gate 202 is formed by patterning, and projections of the edges of the program gate 202 overlap with the active areas 300; or perpendicular projections of the edges of the program gate 202 do not overlap with the perpendicular projections of the active areas 300 on the substrate. Related details are provided above in descriptions regarding the ΔX regions.

When forming the gate structure, the gate dielectric layer can be prepared by thermal oxidation. For example, a silicon oxide layer, a silicon nitride layer, or a hafnium oxide layer of the gate dielectric layer can be prepared by thermal oxidation.

In the presently disclosed 1.5T OTP memory and a method for preparing the same, a program gate can be transferred to an STI structure by only changing the morphology of a gate structure mask without additional process steps, and both sides of each single program gate are programmable separately, so as to achieve a higher density of 1.5T programming, and to increase the integration degree of the OTP memory, thereby realizing miniaturized high-density integration; in addition, anti-fuse structures of the OTP memory utilize electric fields between active areas and respective sides of the program gate, improving the programming efficiency and stability; further, the anti-fuses can be concentrated around the active area divots, making breakdown regions of the anti-fuses more convergent and controllable.

The above-mentioned embodiments are merely illustrative of the principle and effects of the present disclosure instead of restricting the scope of the present disclosure. Any person skilled in the art may modify or change the above embodiments without violating the principle of the present disclosure. Therefore, all equivalent modifications or changes made by those who have common knowledge in the art without departing from the spirit and technical concept disclosed by the present disclosure shall be still covered by the claims of the present disclosure.

1. A 1.5T OTP (One-Time Programmable) memory, comprising:
a semiconductor substrate, comprising an STI structure; and
gate structures, wherein the gate structures are disposed over the semiconductor substrate, and each of the gate structures comprises select gates and a program gate, wherein the program gate is disposed above the STI structure, and wherein edges of the program gate are connected to active areas linked to the select gates through active area divots or STI divots.

2. The 1.5T OTP memory according to claim 1, wherein a perpendicular projection of the program gate and a perpendicular projection of the active areas overlap on the semiconductor substrate.

3. The 1.5T OTP memory according to claim 1, wherein a perpendicular projection of the program gate and a perpendicular projection of the active areas do not overlap on the semiconductor substrate.

4. The 1.5T OTP memory according to claim 1, wherein a lateral length of each of the active area divots or STI divots is less than 200 nm.

5. The 1.5T OTP memory according to claim 1, wherein an axis of symmetry of the program gate along a vertical direction coincides with that of the STI structure, and the select gates are symmetrically distributed with respect to the axis of symmetry of the program gate.

6. The 1.5T OTP memory according to claim 1, wherein adjacent program gates from the gate structures are connected to form at least one program gate line, adjacent select gates from the gate structures are connected to form at least two word lines, and drain regions of the select gates from the gate structures are connected to form at least one bit line.

7. A method for preparing a 1.5T OTP memory, comprising:
providing a semiconductor substrate;
forming an STI structure in the semiconductor substrate; and
forming gate structures over the semiconductor substrate, wherein the gate structures comprise select gates and a program gate, wherein the program gate is disposed above the STI structure, and edges of the program gate are connected to active areas corresponding to the select gates through active area divots or STI divots.

8. The method for preparing the 1.5T OTP memory according to claim 7, wherein the program gate is formed by patterning, and wherein perpendicular projections of the edges of the program gate overlap with perpendicular projections of the active areas on the semiconductor substrate; or wherein the perpendicular projections of the edges of the program gate do not overlap with the perpendicular projections of the active areas on the semiconductor substrate.

9. The method for preparing the 1.5T OTP memory according to claim 7, wherein each of the gate structures comprises a gate dielectric layer, which comprises a silicon oxide layer, a silicon nitride layer, or a hafnium oxide layer.

10. The method for preparing the 1.5T OTP memory according to claim 7, wherein each of the gate structures comprises a gate dielectric layer, which is formed by thermal oxidation.
